(19) United States
(12) Patent Application Publication
(10) Pub. No.: US 2011/0149984 A1
(43) Pub. Date: Jun. 23, 2011

(54) CONFIGURATION MEMORY APPARATUS IN FPGA AND ROUTER SYSTEM USING THE SAME

(75) Inventors: Han Jin CHO, Daejeon (KR); Young Hwan Bae, Daejeon (KR)

(73) Assignee: Electronics and Telecommunications Research Institute, Daejeon (KR)

(21) Appl. No.: 12/961,752

(22) Filed: Dec. 7, 2010

(30) Foreign Application Priority Data
Dec. 18, 2009 (KR) 10-2009-0127494
Jun. 16, 2010 (KR) 10-2010-0057034

(51) Int. Cl. H04L 12/56; G11C 7/10

(52) U.S. Cl. 370/401; 365/189.02

(57) ABSTRACT

Disclosed are a configuration memory apparatus and a router system using the same. The configuration memory apparatus includes: a selection unit selecting one of a first external device and a storage unit and receiving data; a register storing input data received from the selection unit; a storage unit storing data received from the register; and an I/O unit controlling transmission and reception of data to and from the register and a second external device.

### CROSS-REFERENCE TO RELATED APPLICATIONS

This application claims the priority of Korean Patent Application Nos. 10-2009-0127494 filed on Dec. 18, 2009, and 10-2010-0057034 filed on Jun. 16, 2010, in the Korean Intellectual Property Office, the disclosures of which are incorporated herein by reference.

### BACKGROUND OF THE INVENTION

1. Field of the Invention

The present invention relates to a configuration memory apparatus in an FPGA and a router system using the same, and more particularly, to a structure of a configuration memory apparatus devised for effectively using a configuration memory in an FPGA and a structure of a router system using the same.

2. Description of the Related Art

A configuration structure of an FPGA (Field Programmable Gate Array) is designed to be programmable. Thus, a manufactured FPGA can be implemented to fit a user's intention.

The related art FPGA aims at precisely implementing a determined logical circuit. Thus, a structure effective for a point-to-point connection is used as a programmable configuration structure, as requirements for the configuration structure for the FPGA are not very strict.

However, recently, the level of requirements for the FPGA have become so high as to require the implementation of various processors, a high performance IP, a large capacity memory, a high speed I/O, and the like. Namely, beyond the level of a simple slave chip passively performing only an operation required by an external process, presently, the FPGA is required to serve as an SoC (System on Chip) that performs various operations by including a plurality of master chips and slave chips therein.

Thus, the configuration structure used in the related art FPGA cannot satisfy the performance required by a system any longer, and a configuration structure for effectively connecting master chips and slave chips within the FPGA is required.

In addition, in actuality, a majority of the area (approximately 90%) of the entire FPGA chip is allocated to the configuration structure in order to guarantee a large degree of user design flexibility. In particular, because a configuration switch, which occupies very small area, is implemented to have a multiplexer structure, a configuration memory storing configuration information actually occupies the majority of the area of the configuration structure.

However, in general, the amount of configuration memory required in order for the user to implement a designed configuration is merely 5% to 10% of the total amount of configuration memory. Thus, as the size of the FPGA increases, the amount of configuration memory not in use also increases, resulting in the necessity of an effective use of the configuration memory.

### SUMMARY OF THE INVENTION

An aspect of the present invention provides a configuration memory structure that can be effectively used and a router system connecting elements in the FPGA using the same.

According to an aspect of the present invention, there is provided a configuration memory apparatus including: a selection unit selecting one of a first external device and a storage unit and receiving data; a register storing input data received from the selection unit; a storage unit storing data received from the register; and an I/O unit controlling transmission and reception of data to and from the register and a second external device.

According to another aspect of the present invention, there is provided a router system implemented in an FPGA, including: a packet processing apparatus relaying the transmission and reception of a transmission message to and from a different router system; a configuration memory apparatus storing the transmission message transmitted from a hardware core or the packet processing apparatus; and an internal bus connecting the hardware core, the packet processing apparatus and the configuration memory apparatus.

According to another aspect of the present invention, there is provided a router system implemented in an FPGA, including: a packet processing apparatus relaying the transmission and reception of a transmission message to and from a different router system; and a configuration memory apparatus storing the transmission message received from the packet processing apparatus, wherein the router system is implemented in an FPGA.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 illustrates an FPGA structure including a router system according to an exemplary embodiment of the present invention;

FIG. 2 is a schematic block diagram showing functional blocks of a router system according to an exemplary embodiment of the present invention;

FIG. 3 is a schematic block diagram showing functional blocks of a router system according to another exemplary embodiment of the present invention;

FIG. 4 is a schematic block diagram showing functional blocks of a router system according to another exemplary embodiment of the present invention;

FIG. 5 is a schematic block diagram showing functional blocks of a router system according to another exemplary embodiment of the present invention;

FIG. 6 is a schematic block diagram showing functional blocks of a packet processing apparatus according to an exemplary embodiment of the present invention;

FIG. 7 is a schematic block diagram showing functional blocks of a configuration memory apparatus according to an exemplary embodiment of the present invention; and

FIG. 8 is a circuit diagram of the configuration memory apparatus implemented in a circuit stage according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In describing the present invention, if a detailed explanation for a related known function or construction is considered to unnecessarily divert from the gist of the present invention, such explanation will be omitted but would be understood by those skilled in the art.

In the drawings, the shapes and dimensions may be exaggerated for clarity, and the same reference numerals will be used throughout to designate the same or like components.

Unless explicitly described to the contrary, the word “comprise” and variations such as “comprises” or “comprising,” will be understood to imply the inclusion of stated elements but not the exclusion of any other elements.

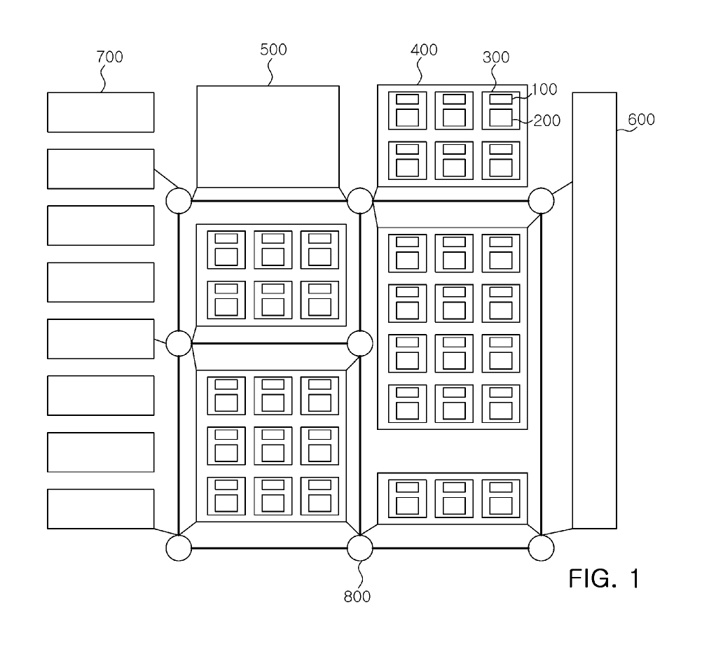

FIG. 1 illustrates an FPGA structure including a router system according to an exemplary embodiment of the present invention.

With reference to FIG. 1, a block memory 600, an input/output buffer 700, a hardware core 500, a logic tile cluster 400, and a router system 800 are disposed in the interior of an FPGA. Recently, an FPGA has been configured in a form equal in performance to a SoC (System on Chip) by mounting the hardware core 500 or the block memory 600 in order to meet user demand.

The hardware core 500 may be a processor, an IP core, or the like, and the block memory 600 may be a large capacity memory resource (e.g., a DRAM, an SRAM, or the like).

The logic tile cluster 400 is a set of logic tiles 300, the basic units of the FPGA. Each of the logic tiles 300 may include a programmable logic module 100 and a configuration memory apparatus 200. The logic module 100 is designed to perform a particular logic task according to a program. The configuration memory apparatus 200 is a storage apparatus storing connection states between the logic modules 100.

With reference to FIG. 1, as the FPGA is configured to be virtually close to an SoC, there arise a necessity for transmitting a large capacity of data between the hardware core 500, the block memory 600, and the logic tile cluster 400, and a necessity for supporting communications between the respective elements in order to guarantee independent operations of the respective elements. Also, the respective elements need to be connected in a one-to-many manner or in a many-to-one manner, as well as in a one-to-one manner.

What is required for supporting such functions is a router. The router enables the respective elements to be connected and to perform communication and supports a great amount of data communications. In order to implement such a router, a part for analyzing an address area from a transmission message and a part for checking whether or not communication with a destination is available and performing communication are required. In addition, a queuing memory for storing the transmission message is required to allow hardware connected to the router to perform a different operation while the operation for communication is being performed.

However, an application of a router system to a general ASIC incurs a large amount of fabrication costs due to a plurality of logics and memories to be assigned to the router system.

Notably, in the case of a general FPGA program, merely 50% to 60% of the logic modules 100 are operated, and only 10% to 20% of the overall configuration memory apparatuses are used. Namely, a great amount of logic modules 100 and configuration memory apparatuses remain not in use.

Therefore, utilization of the logic modules 100 and configuration memory apparatuses 200 not in use would lead to an effective utilization of the FPGA configuration.

Namely, in the case of the FPGA, there are multiple logic modules 100 and multiple configuration memory apparatuses 200, and even after a chip is programmed, a large amount of the elements are not in use which can be utilized for implementing the router system 800.

Thus, the router system 800 according to an exemplary embodiment of the present invention may be implemented by using the logic modules 100 and the configuration memory apparatuses 200. The logic module 100 of the related art may be used for implementing the router system 800 because its function is programmable.

Meanwhile, the configuration memory apparatus 200 stores only connection information between logic modules and outputs information only to connection elements placed at connection portions. Thus, in order to be applied to the router system 800 according to an exemplary embodiment of the present invention, the configuration memory apparatus 200 needs to have a new structure.

Hereinafter, the configuration of the router system 800 will first be described and a description of a new configuration memory apparatus for the router system 800 according to an exemplary embodiment will be made thereafter.

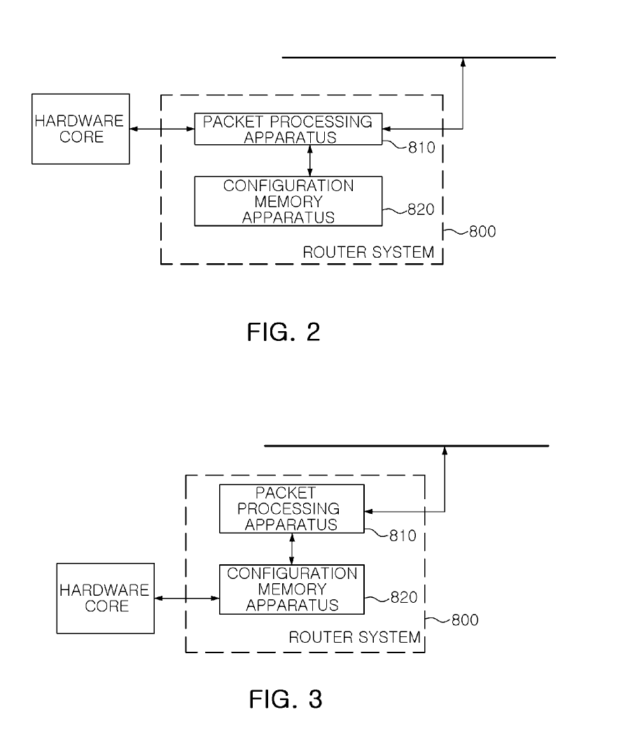

FIG. 2 is a schematic block diagram showing functional blocks of a router system according to an exemplary embodiment of the present invention;

With reference to FIG. 2, the router system 800 according to an exemplary embodiment of the present invention may be configured to include a packet processing apparatus 810 and a configuration memory apparatus 820.

The packet processing apparatus 810 relays transmission and reception of a transmission message between the hardware core 500, the block memory 600, and the logic tile cluster 400, and a different router system.

The packet processing apparatus 810 receives a transmission message from the hardware core 500, the block memory 600, or the logic tile cluster 400, and analyzes the received transmission message. Also, the packet processing apparatus 810 extracts source and destination information included in the transmission message through the analysis.

The packet processing apparatus 810 determines whether or not communication with a router system connected to the destination is available by using the extracted destination information. When communication with the router system is available, the packet processing apparatus 810 transmits the transmission message to the router system connected to the destination by using a connected routing bus. Meanwhile, when the packet processing apparatus 810 is currently processing a different transmission message, it may immediately store the received transmission message in the configuration memory apparatus 820.

According to circumstances, the packet processing apparatus 810 may immediately store the received transmission in the configuration memory apparatus 820.

Also, the router system 800 may receive a transmission message which has been transmitted by the different router system, and transmit the received transmission message to the hardware core 500, the block memory 600, or the logic tile cluster 400 corresponding to a destination. When the corresponding element is operating, the router system 800 may store the received transmission message in the configuration memory apparatus 820, and then, when the corresponding element is available for receiving the transmission message, the router system 800 transmits the transmission message.

The routing bus may be implemented by using a tracking bus not in use in the interior of the FPGA, without the necessity of any additional hardware resources.

The configuration memory apparatus 820 stores the transmission message received by the packet processing apparatus 810 in order to guarantee an independent operation of the hardware core 500, and the like, connected to the packet processing apparatus 810, while the packet processing apparatus 810 is analyzing the transmission message and performing communication. Without the configuration memory apparatus 820, a problem would arise in that the hardware core 500, and the like, would have to wait until such time as the packet processing apparatus 810 transmitted a previously received message.

Namely, when the configuration memory apparatus 820 stores a plurality of transmission messages, the packet processing apparatus 810 can process the plurality of stored transmission messages sequentially or according to the priority order thereof, and the hardware core 500, and the like, can perform a different operation once it transmits the transmission message to the router system 800, and thus, the independent and parallel operation of the hardware core 500, and the like, can be guaranteed.

Preferably, the packet processing apparatus 810 performs an additional function of controlling the configuration memory apparatus 820. With reference to FIG. 2, the packet processing apparatus 810 and the configuration memory apparatus 820 are connected in a one-to-one manner.

Namely, the packet processing apparatus 810 performs a communication function of the router system 800, a function of exchanging data with the hardware core 500, and a function of controlling the router system 800, and the configuration memory apparatus 820 performs only a data storage function.

FIG. 3 is a schematic block diagram showing functional blocks of a router system according to another exemplary embodiment of the present invention.

With reference to FIG. 3, the router system 800 according to an exemplary embodiment of the present invention may be configured to include the packet processing apparatus 810 and the configuration memory apparatus 820.

The configuration memory apparatus 820 receives a transmission message from the hardware core 500, the block memory 600, or the logic tile cluster 400, and stores them. Also, the configuration memory apparatus 820 receives a transmission message, which has been received by the packet processing apparatus 810 via the routing bus, and stores the received transmission message.

The packet processing apparatus 810 analyzes the transmission message stored in the configuration memory apparatus 820. Also, the packet processing apparatus 810 extracts source and destination information included in the transmission message, and checks whether or not communication with a router system connected to the destination is available by using the extracted destination information. When communication with the router system is available, the packet processing apparatus 810 transmits the transmission message to the router system connected to the destination by using the connected routing bus.

Meanwhile, when the packet processing apparatus 810 receives a transmission message from a different router system, it analyzes the received transmission message and stores it in the configuration memory apparatus 820.

In addition, preferably, the packet processing apparatus 810 may perform an additional function of controlling a data exchanged between the hardware core 500, and the like, and the configuration memory apparatus 820.

Namely, the communication function with the router system is performed by the packet processing apparatus 810, and the data storage function and the function of exchanging data with the hardware core 500, and the like, are performed by the configuration memory apparatus 820.

The routing bus may be implemented by using a tracking bus not in use in the interior of the FPGA, without the necessity of any additional hardware resource.

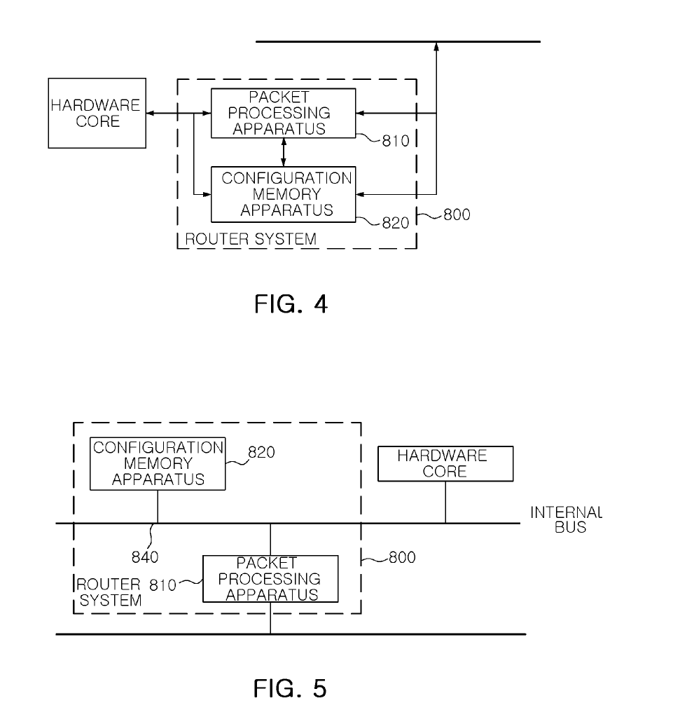

FIG. 4 is a schematic block diagram showing functional blocks of a router system according to another exemplary embodiment of the present invention.

With reference to FIG. 4, the router system 800 according to an exemplary embodiment of the present invention is configured to include the packet processing apparatus 810 and the configuration memory apparatus 820. The packet processing apparatus 810 and the configuration memory apparatus 820 are not only transmitted to the hardware core 500, the block memory 600, or the logic tile cluster 400, but also connected to the routing bus.

In this connection configuration, the router system 800 is operated in the same manner as those described in FIG. 2 or 3, so the operation method of the router system 800 may be altered according to circumstances.

In the case of the connections as illustrated in FIG. 4, preferably, the packet processing apparatus 810 may have a function of controlling the connections of the configuration memory apparatus 820, the routing bus, and the hardware core 500.

The routing bus may be implemented by using a tracking bus not in use in the interior of the FPGA, without the necessity of adding any additional hardware resource.

FIG. 5 is a schematic block diagram showing functional blocks of a router system according to another exemplary embodiment of the present invention.

The router system 800 according to another exemplary embodiment of the present invention is configured to include the packet processing apparatus 810, the configuration memory apparatus 820, and an internal bus 840.

The configuration memory apparatus 820 receives a transmission message from the hardware core 500, the block memory 600, or the logic tile cluster 400, and stores the received message. Also, the configuration memory apparatus 820 receives a transmission message, which has been received by the packet processing apparatus 810 via the routing bus, through the internal bus 840 and stores the received transmission message.

The packet processing apparatus 810 analyzes the transmission message, which has been received from the hardware core 500, the block memory 600, or the logic tile cluster 400, and analyzes the received transmission message.

When necessary, the packet processing apparatus 810 may store the received transmission message in the configuration memory apparatus 820, read it from the configuration memory apparatus 820, and analyze the read transmission message.

Also, the packet processing apparatus 810 extracts source and destination information included in the transmission message, and checks whether or not communication with a router system connected to the destination is available by using the extracted destination information. When communication with the router system is available, the packet processing apparatus 810 transmits the transmission message to the router system connected to the destination by using the connected routing bus. When necessary, the packet processing apparatus 810 may provide control to immediately transfer the transmission message to the hardware core 500, and the like, from the configuration memory apparatus 820.

The configuration memory apparatus 820 and the packet processing apparatus 810 are connected to the internal bus 840. Also, one or more of the hardware core 500, the block memory 600, and the logic tile cluster 400 may be connected to the internal bus 840. Accordingly, the internal elements within the router system 800 can not only exchange data with each other but also exchange data with an external device through the internal bus 840.

The internal bus 840 may be implemented by using a bus not in use in the interior of the FPGA.

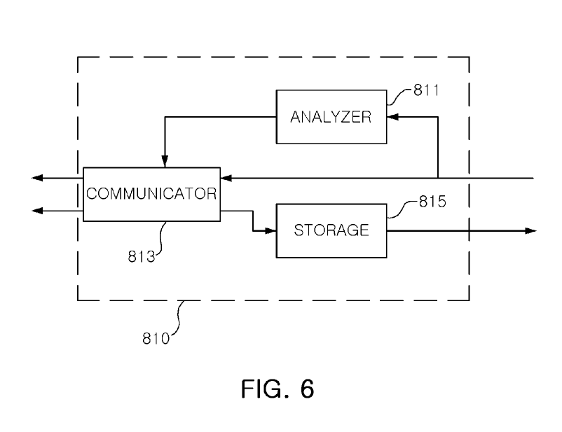

FIG. 6 is a schematic block diagram showing functional blocks of a packet processing apparatus according to an exemplary embodiment of the present invention.

With reference to FIG. 6, the packet processing apparatus 810 may be configured to include an analyzer 811, a communicator 813, and a storage 815.

The analyzer 811 analyzes a transmission message stored in the configuration memory apparatus 820. The analyzer 811 extracts a destination and a source of the transmission message through analysis, and transmits the same to the communicator 813. If a second communicator 814 is provided, the analyzer 811 may transmit the destination and source information also to the second communicator 814.

The communicator 813 is connected to a different router system through the routing bus and performs communication with the different router system. The communicator 813 checks whether or not communication with the different router system is available, and when communication with the different router system is available, the communicator 813 transmits the transmission message.

Although not shown, the packet processing apparatus 810 may further include a second communicator. The second communicator performs communication when the packet processing apparatus 810 is connected to the hardware core 500, the block memory 600, the logic tile cluster 400, or the like.

The storage 815 stores the transmission message, which has been received from the communicator 813, in the configuration memory apparatus 820. When necessary, the storage 815 stores a transmission message, which has been received from the second communicator, in the configuration memory apparatus 820.

The router system designed in the interior of the FPGA according to an exemplary embodiment of the present invention has been described. Hereinafter, a configuration memory structure used for the configuration memory apparatus 820 employed in the router system 800 will now be described.

As discussed above, the general configuration memory apparatus simply receives configuration information and outputs it to each configuration switch. Namely, the related art configuration memory apparatus cannot be used for other purposes.

Thus, in overcoming such shortcomings in the related art configuration memory apparatus, the configuration memory apparatus according to an exemplary embodiment of the present invention has a memory structure that can be utilized for the configuration memory apparatus 820 of the router system 800 by simply adding a smaller number of elements.

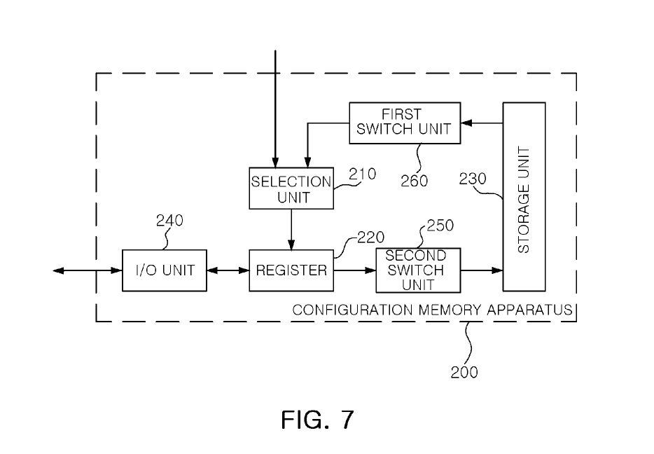

FIG. 7 is a schematic block diagram showing functional blocks of a configuration memory apparatus according to an exemplary embodiment of the present invention.

With reference to FIG. 7, a configuration memory apparatus 200 according to an exemplary embodiment of the present invention may be configured to include a selection unit 210, a register 220, a storage unit 230, and an I/O unit 240. The configuration memory apparatus 200 may further include one or more of a first switch unit 260 and a second switch unit 250.

The selection unit 210 selects one of a first external device and the storage unit 230 and receives data. The first external device may be a device providing configuration information or a different configuration memory apparatus. In general, the configuration memory apparatuses are connected in series in the form of a chain to configure a column.

The register 200 receives the data which has been received by the selection unit 210, and temporarily stores the received data.

The storage unit 230 receives the stored data from the register 220 and stores the same. The storage unit 230 may store the data for a long period of time.

The I/O unit 240 controls a connection between the register 220 and a second external device. The second external device may be the internal bus 840, the packet processing apparatus 810, the hardware core 500, the block memory 600, the logic tile cluster 400, or the like. The I/O unit 240 receives data from the second external device and stores the received data in the register 220, or transmits the data stored in the register 220 to the second external device.

The first switch unit 260 controls a connection between the storage unit 230 and the selection unit 210, and the second switch unit 250 controls a connection between the register 230 and the storage unit 230. Controlling the connections between the selection unit 210 and the storage unit 230 and between the register 220 and the storage unit 230, the first and second switches 260 and 250 serve to prevent the entanglement of a data flow.

With such a configuration, the configuration memory apparatus 200 can store the data received from the second external device and send back the data to the second external device. Namely, the configuration memory apparatus 200 according to an exemplary embodiment of the present invention can serve as a memory device that receives and stores data other than configuration information, and output the stored data.

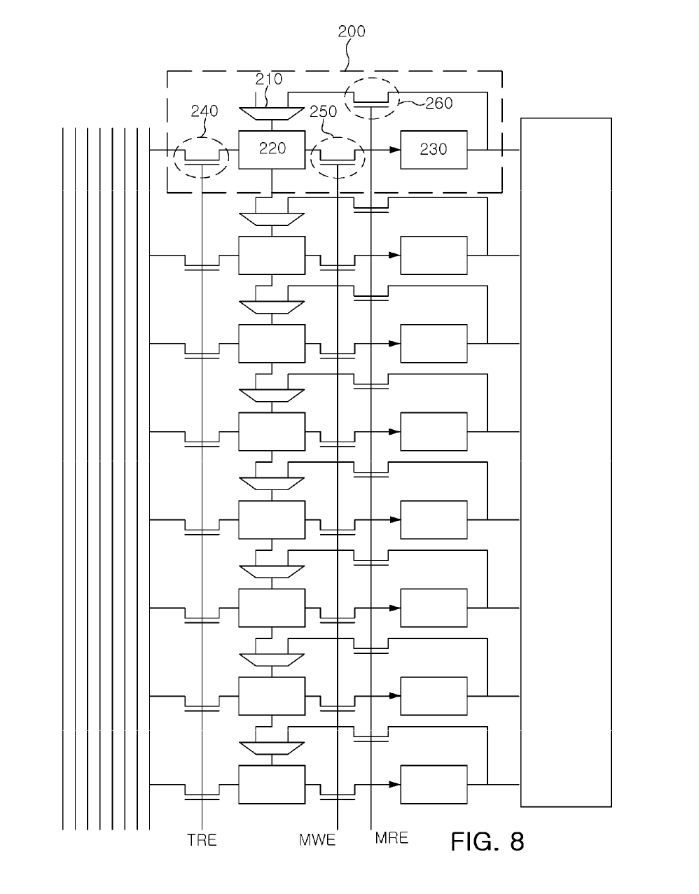

FIG. 8 is a circuit diagram of the configuration memory apparatus implemented in a circuit stage according to an exemplary embodiment of the present invention.

With reference to FIG. 8, the configuration memory apparatus 200 may be implemented to include the selection unit 210, the register 220, the storage unit 230, and the I/O unit 240, the first switch unit 260, and the second switch unit 250.

The selection unit 210 may be implemented by using a multiplexer. When the configuration memory apparatus 200 according to an exemplary embodiment of the present invention is employed for the router system 800, the multiplexer may be configured to receive input data from the storage unit 230.

The I/O unit 240, the first switch unit 260, and the second switch unit 250 may be implemented by using MOSFET switches. The respective switches may be controlled by applying signals to TRE, MRE, and MWE lines.

With reference to the implementation example of the circuit level, the configuration memory apparatus 200 includes merely two additional switches and one additional multiplexer. Thus, the configuration memory apparatus 200 according to an exemplary embodiment of the present invention can be a memory device that can be used for various purposes, while requiring a small amount of additional hardware resource.

As set forth above, according to exemplary embodiments of the invention, the configuration memory in an FPGA can be used as a configuration buffer for a router, so the configuration memory can be effectively used.

In addition, in the router system using the configuration memory structure, the respective elements in the FPGA can be effectively connected without using additional hardware resource, and accordingly, data can be quickly transmitted between the elements, thus improving the performance of the FPGA.

While the present invention has been shown and described in connection with the exemplary embodiments, it will be apparent to those skilled in the art that modifications and variations can be made without departing from the spirit and scope of the invention as defined by the appended claims.

What is claimed is:

1. A configuration memory apparatus comprising:
a selection unit selecting one of a first external device and a storage unit and receiving data;
a register storing input data received from the selection unit;
a storage unit storing data received from the register; and
an I/O unit controlling a transmission and reception of data to and from the register and a second external device.

2. The memory apparatus of claim 1, wherein the selection unit is implemented by using a multiplexer.

3. The memory apparatus of claim 1, further comprising:
a first switch controlling a connection between the storage unit and the selection unit.

4. The memory apparatus of claim 1, further comprising:
a second switch controlling a connection between the register and the storage unit.

5. The memory apparatus of claim 4, wherein the I/O unit comprises a switch structure.

6. A router system comprising:
a packet processing apparatus relaying the transmission and reception of a transmission message to and from a first external device;
a configuration memory apparatus storing the transmission message transmitted from a hardware core or the packet processing apparatus; and
an internal bus connecting the hardware core, the packet processing apparatus and the configuration memory apparatus.

7. The router system of claim 6, wherein the router system is implemented in an FPGA (Field Programmable Gate Array), and the packet processing apparatus is connected to the first external device in the FPGA via a routing bus configured to include a track in the FPGA.

8. The router system of claim 6, wherein the packet processing apparatus comprises:
an analyzer analyzing the transmission message stored in the configuration memory device to extract a source and a destination;
a communicator performing communication with the first external device; and
a storage storing a transmission message received during communications in the configuration memory apparatus,
wherein the analyzer, the communicator, and the storage are implemented by using logic modules in the FPGA.

9. The router system of claim 6, wherein the configuration memory device comprises:
a selection unit selecting one of a second external device and the storage unit and receiving data;
a register storing input data received from the selection unit;
a storage unit for storing the data received from the register; and
an I/O unit controlling a transmission and reception of data to and from the register and the internal bus.

10. The router system of claim 9, wherein the selection unit is implemented by using a multiplexer.

11. The router system of claim 9, further comprising:
a first switch controlling a connection between the storage unit and the selection unit.

12. The router system of claim 9, further comprising:
a second switch unit controlling a connection between the register and the storage unit.

13. A router system comprising:
a packet processing apparatus relaying the transmission and reception of a transmission message to and from a first external device; and
a configuration memory apparatus storing the transmission message received from the packet processing apparatus, wherein the router system is implemented in an FPGA.

14. The router system of claim 13, wherein the router system is implemented in an FPGA (Field Programmable Gate Array), and the packet processing apparatus is connected to the first external device in the FPGA via a routing bus configured to include a track in the FPGA.

15. The router system of claim 13, wherein the packet processing apparatus comprises:
an analyzer analyzing the transmission message stored in the configuration memory device to extract a source and a destination;
a first communicator performing communication with the first external device;
a second communicator performing communication with a hardware core; and
a storage storing a transmission message received while the first and second communicators in communicating with each other, in the configuration memory apparatus,
wherein the analyzer, the first and second communicators, and the storage are implemented by using logic modules in the FPGA.

16. The router system of claim 13, wherein the configuration memory device comprises:
a selection unit selecting one of a second external device and the storage unit and receiving data;
a register storing input data received from the selection unit;
a storage unit for storing the data received from the register; and
an I/O unit controlling a transmission and reception of data to and from the register and the packet processing apparatus.

17. The router system of claim 16, wherein the selection unit is implemented by using a multiplexer.

18. The router system of claim 16, further comprising:
a first switch controlling a connection between the storage unit and the selection unit.

19. The router system of claim 16, further comprising:
a second switch unit controlling a connection between the register and the storage unit.
